(19) United States
(12) Patent Application Publication
(10) Pub. No.: US 2013/0052368 A1
(43) Pub. Date: Feb. 28, 2013

(54) METHODS FOR PREPARING THIN FILMS BY ATOMIC LAYER DEPOSITION USING HYDRAZINES

(71) Applicants: Simon Rushworth, Irby (GB); Paul Williams, Winsford (GB)

(72) Inventors: Simon Rushworth, Irby (GB); Paul Williams, Winsford (GB)

(73) Assignee: SIGMA-ALDRICH CO. LLC, St. Louis, MO (US)

(21) Appl. No.: 13/635,478

(22) PCT Filed: Mar. 14, 2011
(86) PCT No.: PCT/US11/28292

§ 371 Date: Nov. 5, 2012

Related U.S. Application Data
(60) Provisional application No. 61/315,477, filed on Mar. 19, 2010.

(51) Int. Cl. C23C 16/44; C23C 16/50; C23C 16/48

(52) U.S. Cl. 427/569; 427/248.1; 427/582

(57) ABSTRACT

A method of forming a metal-containing film by atomic layer deposition is provided herein. The method comprises using (a) at least one metal fluorinated β-diketonate precursor; and (b) a co-reagent comprising at least one optionally-substituted hydrazine.

### CROSS-REFERENCE TO RELATED APPLICATION

This application claims priority to U.S. Patent Application Ser. No. 61/315,477, a U.S. provisional application filed on 19 Mar. 2010. The disclosure of U.S. Patent Application Ser. No. 61/315,477 is incorporated herein by reference in its entirety.

### FIELD OF THE INVENTION

The present invention relates to methods of preparing thin films by atomic layer deposition (ALD) using at least one metal-containing precursor and at least one optionally-substituted hydrazine.

### BACKGROUND OF THE INVENTION

Various organometallic precursors are used to form thin metal films. A variety of techniques have been used for the deposition of thin films. These include reactive sputtering, ion-assisted deposition, sol-gel deposition, chemical vapor deposition (CVD), and ALD, also known as atomic layer epitaxy. The CVD and ALD processes are being increasingly used as they have the advantages of good compositional control, high film uniformity, good control of doping and, significantly, they give excellent conformal step coverage on highly non-planar microelectronics device geometries.

ALD is one method for the deposition of thin films. It is a self-limiting, sequential, unique film growth technique based on surface reactions that can provide atomic layer-forming control and deposit conformal-thin films of materials provided by precursors onto substrates of varying compositions. In ALD, the precursors are separated during the reaction. The first precursor is passed over the substrate producing a monolayer on the substrate. Any excess unreacted precursor is pumped out of the reaction chamber. A second precursor is then passed over the substrate and reacts with the first precursor, forming a second monolayer of film over the first-formed monolayer of film on the substrate surface. This cycle is repeated to create a film of desired thickness. ALD film growth is self-limited and based on surface reactions, creating uniform depositions that can be controlled at the nanometer-thickness scale.

Thin films have a variety of important applications, such as glazing applications, nanotechnology and fabrication of semiconductor devices. Examples of more specific applications include high-refractive index optical coatings, corrosion-protection coatings, photocatalytic self-cleaning glass coatings, biocompatible coatings, dielectric capacitor layers and gate dielectric insulating films in FETs (Field-Effect Transistor), capacitor electrodes, gate electrodes, adhesive diffusion barriers and integrated circuits.

Techniques, such as sputtering and CVD, to form thin films are limited due to the number of pin-holes or voids present in layers deposited by these techniques. A number of precursors, such as silver and copper precursors, have been reported for CVD and indeed high purity films can be obtained by thermal decomposition of these materials on a substrate. However, the temperatures required (200° C. or above) are not compatible with the achievement of very thin films as defined herein. The elevated temperatures involved using CVD lead to surface roughening and even formation of “balls”, e.g. silver balls, which are not connected resulting in a coating of nanoparticulates and low or non-existent film continuity. If the temperature is reduced to avoid this effect, the percursors are not decomposed fully. This results in highly contaminated deposits or no deposition at all. Any prior art for CVD is therefore not applicable to this invention.

International Publication No. WO 2009/039216 reports CVD and ALD of gold, silver and copper thin films.

U.S. Pat. No. 6,613,924 to Welch et al. report silver precursors for CVD processes.

U.S. Pat. No. 6,464,779 to Powell et al. report copper precursors for ALD processes.

The methods of the invention disclosed herein use a metal-containing precursor and a hydrazine to allow a true ALD process to be performed. The invention avoids the limitation of other deposition techniques and allows for very thin films to be formed with enhanced continuity. One advantage of the current invention over CVD is that lower temperatures can be employed, thus allowing the formation of thinner, highly pure films with enhanced continuity.

### SUMMARY OF THE INVENTION

In one embodiment, a method for forming a metal-containing film by atomic layer deposition is provided. The method comprises using

(a) at least one metal fluorinated β-diketonate precursor; and

(b) a co-reagent comprising at least one optionally-substituted hydrazine.

In another embodiment, a method for providing solar control on a glass substrate is provided. The method comprises forming a metal-containing film by an ALD process directly or indirectly on the glass substrate; wherein the ALD process uses at least one metal fluorinated β-diketonate complex and at least one optionally-substituted hydrazine.

Other embodiments, including particular aspects of the embodiments summarized above, will be evident from the detailed description that follows.

### BRIEF DESCRIPTION OF THE DRAWINGS

FIG. 1 is a graphical representation of Ag film thickness (nm) vs. substrate temperature using (hfac)AgCOD and tertiary-butylhydrazine in ALD growth for 500 cycles.

FIG. 2 is a graphical representation of X-Ray Diffraction (XRD) data for Ag films deposited at substrate temperatures of 70° C., 90° C. and 110° C.

FIG. 3 is a graphical representation of sheet resistance v. average film thickness for Ag films deposited using (hfac)AgCOD and tertiary-butylhydrazine in ALD growth for 750 cycles with a substrate temperature of 110° C. (or using isopropanol for comparison).

### DETAILED DESCRIPTION OF THE INVENTION

In various aspects of the invention, methods of making metal-containing films by ALD are provided. In general, it has been found that when metal, particularly Group 1B (also known as Group IB and Group 11) metal, precursors are used with hydrazine co-reagents in ALD, very thin and enhanced continuous films can be produced at low deposition temperatures.

The use of various substituted hydrazines as co-reagents in metal ALD has been reported for nickel ALD, see U.S. 2003/0201541. However the temperatures are all above 100° C. and as mentioned above the target deposition range to avoid “balling” is 60-70° C. Further, the use of hydrazines with other metals, such as in U.S. 2003/0201541, has been used to achieve metal nitride films. Therefore, the use of hydrazines to produce highly pure films with no nitrogen inclusions is surprising. The deposition of metals by ALD at such low temperatures also opens up applications for deposition on to plastics.

Therefore, in a first embodiment, a method for forming a metal-containing film by atomic layer deposition is provided. The method comprises using

(a) at least one metal fluorinated β-diketonate precursor; and

(b) a co-reagent comprising at least one optionally-substituted hydrazine.

As used herein, the term “precursor” refers to an organometallic molecule, complex and/or compound which is deposited or delivered to a substrate to form a thin film by a vapor deposition process such as ALD.

Examples of fluorinated β-diketonate ligands include, without limitation, hexafluoropentanedionate (also known as hexafluoroacetylacetate (“hfac”)); trifluoropentanedionate (also known as trifluoroacetylacetonate (“tfac”)); thenoyltrifluoroacetetonate (also known as “ttfa”); and bis(6,6,7,7,8,8,8-heptafluoro-2,2-dimethyl-3,5-octanedionate (also known as “fod”).

In one embodiment, a metal fluorinated β-diketonate precursor used in the methods of the invention corresponds in structure to the following Formula:

(fluorinated β-diketonate)MX

wherein M is a metal; X is a neutral ligand; and the fluorinated β-diketonate is selected from the group consisting of hfac, tfac, ttfa and fod.

In a particular embodiment, M is a Group 1B metal, such as copper, silver or gold.

The neutral ligand, X, as used herein, is a ligand that provides a stabilizing effect on the metal center by forming a coordination complex. Electron density is provided in a donor bond, but said ligand is not charged.

The neutral ligand, X, can be any neutral ligand that lends itself well to providing a thin, continuous film by ALD. Examples of neutral ligands that can be used include, without limitation, 1,5-cyclooctadiene (“COD”), triethylphosphine, trimethylphosphine, triphenylphosphine, triethylphosphate, trimethylphosphate, vinyltriethylsilane (“VTES”), vinyltrimethylsilane, tetramethylethylenediamine (“TMED”), ethylenediamine, tetramethylpropylenediamine, tertiarybutylisocyanate, bistrimethylacetylene, allyl, methylallyl, dimethylallyl, butadiene and dimethylbutadiene.

In a particular embodiment, a metal fluorinated β-diketonate precursor used in the methods of the invention corresponds in structure to Formula I:

(hfac)MX Formula I

wherein M is a metal as described above, and X is a neutral ligand as described above.

For example, in one embodiment (hfac)AgCOD can be used as the silver precursor (also known as silver hexafluoropentanedionate cyclooctadiene complex). Another example is (hfac)AgTMED (also known as silver hexafluoropentanedionate tetramethylethylenediamine). Another example is (hfac)AgVTES (also known as silver hexafluoropentanedionate vinyltriethylsilane).

In a particular embodiment, (hfac)AgCOD is used as the silver precursor.

Alternatively, copper precursors can be used such as (hfac)CuCOD, (hfac)CuTMED, and (hfac)CuVTES. In a particular embodiment, (hfac)CuCOD is used as the copper precursor.

Further, the metal precursor may be dissolved in an appropriate hydrocarbon or amine solvent. Appropriate hydrocarbon solvents include, but are not limited to, aliphatic hydrocarbons, such as hexane, heptane and nonane; aromatic hydrocarbons, such as toluene and xylene; aliphatic and cyclic ethers, such as diglyme, triglyme and tetraglyme. Examples of appropriate amine solvents include, without limitation, octylamine and N,N-dimethyldodecylamine. For example, the precursor may be dissolved in toluene to yield a 0.05 to 1M solution.

The methods of the invention also involve using an optionally-substituted hydrazine as a co-reagent during the ALD process.

In one embodiment, the hydrazine is not substituted.

In another embodiment, the hydrazine is substituted with an aryl group such as phenyl.

As used herein, the term “aryl” refers to an aromatic carbocyclyl containing from six to 14 carbon ring atoms. Examples of aryls include phenyl, benzyl, tolyl and xylyl.

In another embodiment, the hydrazine is substituted with one or more alkyl groups, such as methyl, ethyl, propyl, butyl, etc.

As used herein, the term “alkyl” refers to a saturated hydrocarbon chain of 1 to about 8 carbon atoms in length, such as, but not limited to, methyl, ethyl, propyl, butyl, pentyl, hexyl, heptyl and octyl. The alkyl group may be straight-chain or branched-chain. “Alkyl” is intended to embrace all structural isomeric forms of an alkyl group. For example, as used herein, propyl encompasses both n-propyl and iso-propyl; butyl encompasses n-butyl, sec-butyl, iso-butyl and tert-butyl. Further, as used herein, “Me” refers to methyl, “Et” refers to ethyl, “iPr” refers to iso-propyl and “tBu” refers to tert-butyl.

Examples of hydrazines which may be used as a co-reagent, without limitation, include hydrazine, t-butylhydrazine, phenylhydrazine, methylhydrazine and dimethylhydrazine.

The methods of forming metal-containing thin films herein use an atomic layer deposition process. The ALD methods of the invention encompass various types of ALD such as, but not limited to, conventional processes, liquid injection processes, plasma-enhanced processes and photo-assisted processes.

In one embodiment, conventional and/or pulsed injection ALD is used to form a metal-containing film. For conventional and/or pulsed injection ALD process see, for example, George S. M., et. al. J. Phys. Chem. 1996. 100:13121-13131.

In another embodiment, liquid injection ALD is used to form a metal-containing thin film using at least one metal fluorinated β-diketonate precursor and at least one optionally-substituted hydrazine.

In one embodiment, the metal fluorinated β-diketonate precursor and the optionally-substituted hydrazine are delivered to a reaction chamber or substrate by liquid injection as opposed to vapor draw by a bubbler. For liquid injection ALD process see, for example, Potter R. J., et. al. Chem. Vap. Deposition. 2005. 11(3):159.

Examples of liquid injection ALD growth conditions include, but are not limited to:
(1) Substrate temperature: 50-300° C.
(2) Evaporator temperature: 100-150° C.
(3) Reactor pressure: 1-100 mbar
(4) Solvent: toluene, or any solvent mentioned above
(5) Solution concentration: 0.05-0.2 M
(6) Injection rate: about 2.5 μl pulse⁻¹ (4 pulses cycle⁻¹)
(7) Inert gas flow rate: 100-300 cm³ min⁻¹
(8) Reactive gas flow rate: 0-200 cm³ min⁻¹
(9) Pulse sequence (sec.) (precursor/purge/reactive gas/purge): will vary according to chamber size.
(10) Number of cycles: will vary according to desired film thickness.

In another particular embodiment, the metal fluorinated β-diketonate precursor is delivered to a reaction chamber or substrate by liquid injection, while the optionally-substituted hydrazine is delivered to a reaction chamber or substrate by vapor draw using a bubbler.

In another embodiment, photo-assisted ALD is used to form a metal-containing thin film using at least one metal fluorinated β-diketonate precursor and at least one optionally-substituted hydrazine. For photo-assisted ALD processes see, for example, U.S. Pat. No. 4,581,249.

Thus, the metal fluorinated β-diketonate precursors utilized in these methods may be liquid, solid, or gaseous. Preferably, the precursors are liquid at ambient temperatures with high vapor pressure allowing for consistent transport of the vapor to the process chamber.

In one embodiment, only one metal fluorinated β-diketonate precursor is used in the ALD process. In another embodiment, two or more metal fluorinated β-diketonate precursors can be used in the ALD process.

In another embodiment a “mixed” metal film is formed. At least one “co-precursor” may be used to form a “mixed” metal film. As used herein, a mixed-metal film contains at least two different metals. In a particular embodiment, a metal fluorinated β-diketonate precursor, particularly a Group 1B metal precursor according to the invention, may be used in ALD with at least one Zr, Ti, Ta, Si, Fe, Ru, Ni, Mn, Rh, W and/or Ir precursor to form a mixed-metal containing film.

In another embodiment, one or more additional co-reagent(s) can be used in forming a thin film by ALD. For example, an additional co-reagent could be pulsed in sequentially. Examples of such additional co-reagents include, but are not limited to, hydrogen, hydrogen plasma, ammonia, borane, silane or any combination thereof.

A variety of substrates can be used in the methods of the present invention to support thin films. For example, the precursors disclosed herein may be delivered for deposition to substrates such as, but not limited to, plastic, glass, silicon, silicon oxide, silicon nitride, tantalum, tantalum nitride, copper, ruthenium, titanium nitride, tungsten and tungsten nitride.

As mentioned above, the use of a metal fluorinated β-diketonate precursor and a hydrazine in ALD allows lower deposition temperatures to be used to attain an enhanced continuous film. Therefore, in one embodiment, the film is grown at a temperature ranging from about 60° C. to about 70° C.

The methods of the invention allow the growth of very thin films. In one embodiment, the “thin” film formed has a maximum thickness of 50 nm, preferably less than 20 nm and more preferably less than 10 nm.

Further, the methods of the invention are used to form highly pure films. For example, the films have minimal to no inclusions. When a pure film is formed with the methods of the invention, the term “pure” is meant to embrace a film containing about 0.1% or less contamination. The films are phase pure with minimal grain boundaries to maximize conductivity.

Additionally, the methods of the invention allow for films with enhanced continuity. Enhanced continuity refers to a film having substantially full coalescence of the initial film nucleation sites. The object is to have as many sites as possible with full surface coverage as quickly as possible, i.e. in as thin a film as possible. Getting a continuous film to form from the initial deposition sites involves promoting 2D growth and then joining up sections seamlessly, i.e. without large grain boundary disruptions which can isolate different areas and stop current flow. An enhanced continuous film formed by the ALD method herein, is flatter and the surface roughness is as low as possible to avoid visible light scattering and plasmonic absorption in the visible spectral range. The average roughness should be less than about 3 nm and preferably less than about 2 nm. Finally, the enhanced continuous film is likely to be denser which is good for low optical absorption and high conductivity.

The metal-containing films described herein have various applications.

In one embodiment, the metal-containing film is used in a glazing application on a glass substrate to provide solar control. The current low E glass coatings are based on optically transparent or transparent conducting oxide (TCO) materials. The deposition processes currently employed (sputtering) cannot provide pin-hole free films at very low thicknesses. Therefore, less than optimum properties are currently available. Thicker films of necessity increase light absorption and reduce transparency, which is not ideal for glazing applications where visible light transmission through the coating is desired to be as high as possible. The ALD process disclosed herein can provide more uniform coatings that are more continuous and pin hole free at lower thicknesses. Thus, transparency values are not compromised and functionality of the coating is still high.

Therefore, in one embodiment, a method is provided for providing solar control on a glass substrate. The method comprises forming a metal-containing film, preferably a Group 1B metal film, by an ALD process directly or indirectly on the glass substrate; wherein the ALD process uses at least one metal fluorinated β-diketonate precursor and at least one optionally-substituted hydrazine.

The at least one metal fluorinated β-diketonate precursor and at least one optionally-substituted hydrazine are as described herein.

In another embodiment, the methods of the invention are used to create or grow metal-containing thin films which can display high conductivity for use in devices as an electrode material.

The metal-containing films described herein can be used for applications such as dynamic random access memory (DRAM) and complementary metal oxide semi-conductor (CMOS) for memory and logic applications on, for example, silicon chips. The metal-containing films can be used in such devices as gate electrodes or metallization contacts, etc.

In one embodiment, the metal-containing film formed has a resistivity of less than about 15 μΩ/cm. In a particular embodiment, the metal-containing film formed has a resistivity of less than about 5 μΩ/cm. In a further particular embodiment, the metal-containing film formed has a resistivity of less than about 4.2 μΩ/cm.

In another embodiment, the metal-containing film has a sheet resistance less than about 20Ω/□. In particular embodiment, the metal-containing film has a sheet resistance less than about 5Ω/□. In a further particular embodiment, the metal-containing film has a sheet resistance less than about 3.9Ω/□. The common unit for sheet resistance is “ohms per square” (denoted “Ω/sq” or “Ω/□”).

In a particular embodiment, the metal-containing film has a thickness of about 12 nm and the sheet resistance mentioned above.

### EXAMPLES

The following examples are merely illustrative, and do not limit this disclosure in any way.

### Example 1

An ALD process has been developed using a silver precursor ((hfac)AgCOD) and a substituted hydrazine (tertiary-butylhydrazine, TBH). Alternate pulses of these precursors with purge steps in-between have been demonstrated to be well suited for formation of a coherent, continuous silver film at a variety of temperatures. By reducing the temperature the nucleation density is increased which significantly enhances film properties. Deposition was achieved at temperatures as low as 60-70° C. Experimental details are as follows.

The (hfac)AgCOD precursor was delivered to a glass substrate by liquid injection of a precursor solution (0.2M in toluene) and subsequent flash evaporation, whereas the TBH was delivered as neat precursor vapors by a vapor draw set up. Table 1 below presents the conditions.

TABLE 1
Process parameters used for Ag film deposition

| | Growth method | |
|---|---|---|
| | ALD growth | ALD growth |
| Growth parameter | n-propanol | t-butylhydrazine |
| Temperature (° C.) | 250° C.-130° C. | 130° C.-60° C. |
| Reactor pressure (mbar) | 1 | 5 |
| Injector frequency (Hz) | 2 | 2 |
| Run time (mins) | ~135 | 30 |
| Cycle components | Inject/Purge/ | Inject/Purge/TBH/Purge |
| | Propanol/Purge | (5 s @ 8 Hz)/2/0.5/2 |
| | 2/2/0.5/3.5 | |
| No. cycles | 1000 | 300 |
| Carrier gas | Argon | Argon |
| Carrier gas flow (sccm) | 200 | 200 |
| Vaporizer temperature | 130 | 130 |
| (° C.) | | |

Initially films were grown by ALD at 130° C., 110° C., 90° C. and 70° C. with the (hfac)AgCOD precursor and TBH on a glass substrate.

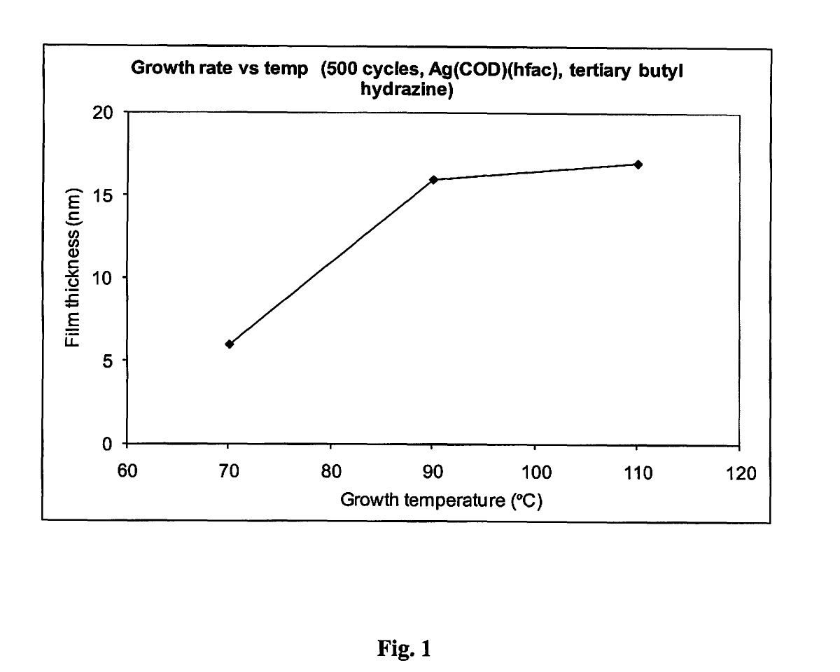

In a comparison study, use of alcohol as a co-reagent (in this case n-propanol) was limited to deposition at temperatures to 110° C. (i.e. deposition with n-propanol effectively stopped at substrate temperatures of ˜110° C.) Whereas, film growth occurred with TBH even at 60° C. (˜6 nm). FIG. 1 demonstrates growth rate using (hfac)AgCOD precursor and TBH.

The silver films have been characterized and their microstructure correlated with the deposition parameters. The grain size of the films generally decreases with decreasing deposition temperature. This is accompanied by an increase in nucleation density.

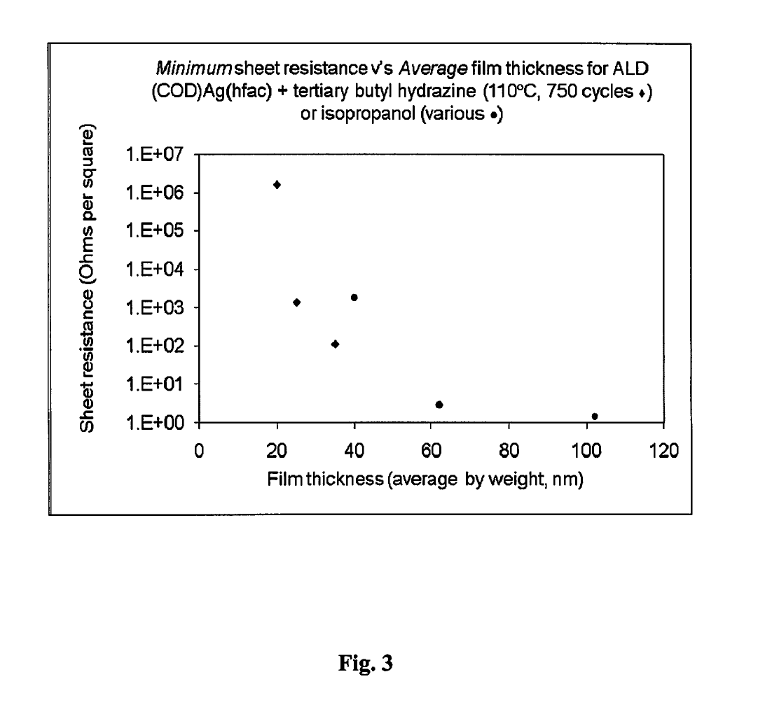

The electrical conductivity was measured in films grown at 110° C. at film thicknesses of approximately 20-25 nm. The electrical properties of ALD silver films deposited onto glass substrates were assessed using four-point probe measurements. Some of the measurements are summarized in FIG. 3 which shows the relationship between sheet resistance and film thickness.

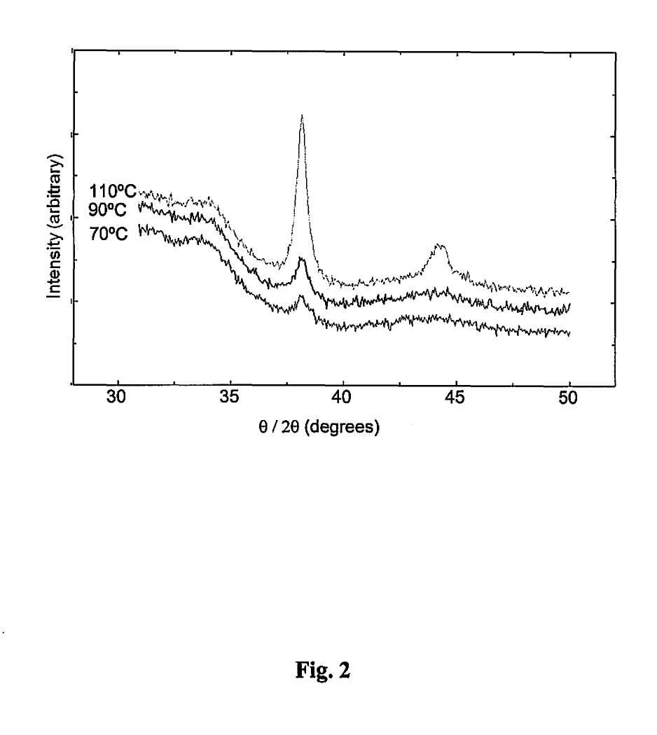

The crystallinity of the film increases with deposition temperature however peaks assigned to crystalline silver phases are clearly seen by XRD (See FIG. 2).

All patents and publications cited herein are incorporated by reference into this application in their entirety.

The words “comprise”, “comprises”, and “comprising” are to be interpreted inclusively rather than exclusively.

What is claimed is:

1. A method for forming a metal-containing film by atomic layer deposition, the method comprising using
(a) at least one metal fluorinated β-diketonate precursor; and
(b) a co-reagent comprising at least one optionally-substituted hydrazine.

2. The method of claim 1, wherein the metal comprises a Group 1B metal.

3. The method of claim 2, wherein the metal comprises copper or silver.

4. The method of claim 1, wherein the fluorinated β-diketonate is selected from the group consisting of hexafluoroacetylacetate (hfac); trifluoroacetylacetonate (tfac); thenoyltrifluoroacetetonate (ttfa); and bis(6,6,7,7,8,8,8-heptafluoro-2,2-dimethyl-3,5-octanedionate (fod).

5. The method of claim 2, wherein the at least one metal fluorinated β-diketonate precursor corresponds in structure to Formula I:
(hfac)MX Formula I
wherein M is a Group 1B metal and X is a neutral ligand.

6. The method of claim 5, wherein M comprises copper or silver, and X is selected from the group consisting of 1,5-cyclooctadiene (COD), triethylphosphine, trimethylphosphine, triphenylphosphine, triethylphosphate, trimethylphosphate, vinyltriethylsilane (VTES), vinyltrimethylsilane, tetramethylethylenediamine (TMED), ethylenediamine, tetramethylpropylenediamine, tertiarybutylisocyanate, bistrimethylacetylene, allyl, methylallyl, dimethylallyl, butadiene and dimethylbutadiene.

7. The method of claim 5, wherein the at least one metal fluorinated β-diketonate precursor is selected from the group consisting of (hfac)AgCOD, (hfac)AgTMED, (hfac)AgVTES, (hfac)CuCOD, (hfac)CuTMED and (hfac)CuVTES.

8. The method of claim 5, wherein the at least one metal fluorinated β-diketonate precursor is (hfac)AgCOD or (hfac)CuCOD.

9. The method of claim 1, wherein the co-reagent is selected from the group consisting of hydrazine, t-butylhydrazine, phenylhydrazine, dimethylhydrazine and methylhydrazine.

10. The method of claim 1, wherein the atomic layer deposition is photo-assisted atomic layer deposition.

11. The method of claim 1, wherein the atomic layer deposition is liquid injection atomic layer deposition.

12. The method of claim 1, wherein the atomic layer deposition is plasma-enhanced atomic layer deposition.

13. The method of claim 1, wherein the least one metal fluorinated β-diketonate precursor is delivered to a substrate by liquid injection.

14. The method of claim 13, wherein the at least one optionally-substituted hydrazine is delivered to a substrate by vapor draw.

15. The method of claim 1, wherein the at least one metal fluorinated β-diketonate precursor is dissolved in an organic solvent.

16. The method of claim 15, wherein the organic solvent is selected from the group consisting of toluene, heptane, octane, nonane and tetrahydrofuran.

17. The method of claim 1, comprising using
(a) at least one metal fluorinated β-diketonate precursor;
(b) a co-reagent comprising at least one optionally-substituted hydrazine; and
(c) a further co-reagent selected from the group consisting of hydrogen, hydrogen plasma, ammonia, borane, silane, and a combination thereof.

18. The method of claim 1, wherein the at least one precursor is delivered to a substrate selected from the group consisting of glass, plastic, silicon, silicon oxide, silicon nitride, tantalum, tantalum nitride, copper, ruthenium, titanium nitride, tungsten, and tungsten nitride.

19. The method of claim 1, wherein the film is formed at a temperature from about 60° C. to about 70° C.

20. The method of claim 1, wherein the film is used for a memory or logic application.

21. The method of claim 20, wherein the method is used for a DRAM or CMOS application.

22. The method of claim 1, wherein the film is formed directly or indirectly on a glass substrate.

23. The method of claim 1, wherein the film has a resistivity of less than about 15 μΩ/cm.

24. The method of claim 23, wherein the film has a resistivity of less than about 5 μΩ/cm.

25. The method of claim 24, wherein the film has a resistivity of less than about 4.2 μΩ/cm.

26. The method of claim 1, wherein the film has a thickness of about 12 nm and has a sheet resistance less than about 20Ω/□.

27. The method of claim 26, wherein the film has a sheet resistance less than about 5Ω/□.

28. The method of claim 27, wherein the film has a sheet resistance less than about 3.9Ω/□.

29. A method for providing solar control on a glass substrate, the method comprising forming a metal-containing film by an ALD process directly or indirectly on the glass substrate; wherein the ALD process uses at least one metal fluorinated β-diketonate precursor and at least one optionally-substituted hydrazine.
